(19) United States
(12) Patent Application Publication
(10) Pub. No.: US 2025/0038039 A1
(43) Pub. Date: Jan. 30, 2025

(54) LIFT PINS, LIFT PIN ARRANGEMENTS, SEMICONDUCTOR PROCESSING SYSTEMS, AND METHODS OF MAKING LIFT PIN ARRANGEMENTS FOR SEMICONDUCTOR PROCESSING SYSTEMS

(71) Applicant: ASM IP Holding B.V., Almere (NL)

(72) Inventors: Ion Hong Chao, Gilbert, AZ (US); Kai Zhou, Phoenix, AZ (US); Peipei Gao, Chandler, AZ (US); Wentao Wang, Chandler, AZ (US); Han Ye, Phoenix, AZ (US); Kishor Patil, Chandler, AZ (US); Fan Gao, Chandler, AZ (US); Xing Lin, Chandler, AZ (US); Alexandros Demos, Scottsdale, AZ (US)

(21) Appl. No.: 18/785,702

(22) Filed: Jul. 26, 2024

Related U.S. Application Data
(60) Provisional application No. 63/529,490, filed on Jul. 28, 2023.

(51) Int. Cl. H01L 21/687

(52) U.S. Cl. CPC H01L 21/68742; H01L 21/68757

(57) ABSTRACT

A lift pin includes a lift pin body arranged along a lift pin axis having a contact pad, a stem segment, a neck segment, and a span feature. The contact pad is defined at a first end of the lift pin body, the stem segment extends from the contact pad, and the neck segment extends from the stem segment. The span feature is defined at a second end of the lift pin body, is connected to the contact pad by the neck segment and the stem segment, and has a minor and major widths. The minor width is equivalent to a neck diameter defined by the neck segment, the major with is greater than the minor width, and the major width is greater than a stem diameter defined by the stem segment. Lift pin arrangements, semiconductor processing systems, and methods of making semiconductor processing systems are also described.

### CROSS-REFERENCE TO RELATED APPLICATIONS

This application is a nonprovisional of, and claims priority to and the benefit of, U.S. Provisional Patent Application No. 63/529,490, filed Jul. 28, 2023 and entitled “LIFT PINS, LIFT PIN ARRANGEMENTS, SEMICONDUCTOR PROCESSING SYSTEMS, AND METHODS OF MAKING LIFT PIN ARRANGEMENTS FOR SEMICONDUCTOR PROCESSING SYSTEMS,” which is hereby incorporated by reference herein.

### FIELD OF INVENTION

The present disclosure generally relates to depositing material layer onto substrates. More particularly, the present disclosure relates to seating and unseating substrates from substrate supports prior to and subsequent to deposition of material layers onto substrates, such as during the deposition of material layers during the fabrication of semiconductor devices.

### BACKGROUND OF THE DISCLOSURE

Material layers are commonly deposited onto substrates during the fabrication of semiconductor devices, such as during the fabrication of logic and memory devices. Material layer deposition is generally accomplished by seating the substrate on a substrate support within a reaction chamber, heating the substrate to a desired deposition temperature, and exposing the substrate to a material layer precursor under environmental conditions selected to cause a material layer to deposit onto the substrate. Once the material layer develops desired properties exposure of the substrate to the material layer precursor typically ceases, the substrate is unseated from the substrate support, and the substrate removed from the reactor chamber to undergo further processing, as appropriate for the semiconductor device being fabrication. Seating may be accomplished using lift pins, which are generally slidably received within the substrate, and which slide through the substrate to seat and unseat the substrate from the substrate support.

One challenge to the use of lift pins for seating and unseating substrates within reaction chamber using lift pins is material accretion within mechanical clearances defined within the interior of the reaction chamber, such as between the lift pin and substrate support. For example, in some material layer deposition operations, material may accrete on the stem of the lift pin. The accreted material may be carried by the stem of the lift pin during movement of the lift pin through the substrate support, potentially increasing resistance to sliding movement of the lift pin through the substrate support and/or causing the lift pin to bind within the substrate support. Material may also accrete on the tips of the lift pins when seated on the substrate, increasing force that need be applied to the lift pin to initiate sliding of the lift pin through the substrate support to unseat the substrate from the substrate support once deposition of the material layer is complete.

Various countermeasures exist to limit lift pin binding within substrates. For example, the lift pin may be maintained at a temperature differing from that required for material layer deposition within the reaction chamber, limiting the tendency of material to accrete on the lift pin. The lift pin may be separated from the material layer precursor employed during the deposition process, for example by arranging the lift pin within a bellows or providing a purge to the lift pin stem, also limiting the tendency of material to accrete on the lift pin during deposition of the material layer onto the substrate. And the interior of the reaction chamber may be etched subsequent to deposition of the material layer onto the substrate, removing accreted material prior to the accretion reaching size sufficient to cause the lift pin to bind within the substrate support. While generally satisfactory for their intended purpose, such countermeasures can add complexity to the reaction chamber architecture and/or increase cost of ownership of the reaction chamber due to increased usage of consumables and/or reduced reaction chamber throughput.

Such systems and methods have generally be satisfactory for their intended purpose. However, there remains a need for improved lift pins, lift pin arrangements and semiconductor processing systems, and methods of making lift pin arrangements for semiconductor processing systems. The present solution provides a solution this need.

### SUMMARY OF THE DISCLOSURE

A lift pin is provided. The lift pin includes a lift pin body arranged along a lift pin axis and having a contact pad, a stem segment, a neck segment, and a span feature. The contact pad is defined at a first end of the lift pin body, the stem segment extends from the contact pad, and the neck segment extends from the stem segment. The span feature is defined at a second end of the lift pin body, is connected to the contact pad by the neck segment and the stem segment of the lift pin body, and has a minor width and a major width. The minor width of the span feature is substantially equivalent to a neck diameter defined by the neck segment of the lift pin body, the major width of the span feature is greater than the minor width of the span feature, and the major width of the span feature is further greater than a stem diameter defined by the neck segment of the lift pin body.

In addition to one or more of the features described above, or as an alternative, further examples may include that the lift pin body is formed from a ceramic material.

In addition to one or more of the features described above, or as an alternative, further examples may include that the minor width is offset from the major width by about 90 degrees about the lift pin axis.

In addition to one or more of the features described above, or as an alternative, further examples may include that the span feature has a major lobe and a minor lobe, the major width spanning the major lobe and the minor width spanning the minor lobe.

In addition to one or more of the features described above, or as an alternative, further examples may include that the major lobe is a first major lobe and the span feature has a second major lobe separated from the first major lobe by the minor lobe.

In addition to one or more of the features described above, or as an alternative, further examples may include that the second major lobe is offset from the first major lobe by about 180 degrees.

In addition to one or more of the features described above, or as an alternative, further examples may include that the minor lobe is a first minor lobe and the span feature has a second minor lobe, wherein the second minor lobe is separated from the first minor lobe by the major lobe.

In addition to one or more of the features described above, or as an alternative, further examples may include that the second minor lobe is offset from the first minor lobe by about 180 degrees.

In addition to one or more of the features described above, or as an alternative, further examples may include that the span feature has a first planar facet and a second planar facet, and wherein a major width intersects both the first planar facet and the second planar facet.

In addition to one or more of the features described above, or as an alternative, further examples may include that the span feature has two or more arcuate facets defined between the major width and a minor width.

In addition to one or more of the features described above, or as an alternative, further examples may include that the span feature has an intermediate planar facet offset from both the major width and the minor width.

In addition to one or more of the features described above, or as an alternative, further examples may include that the first planar facet and the second planar facet are two of at least six planar facets defined by the span feature, wherein the span feature has at least eight arcuate facets.

A lift pin arrangement is provided. The lift pin arrangement includes a lift pin as described above and a lift pin weight with a weight body. The weight body has a through-aperture extending therethrough with a flanged segment thereon. The lift pin body is slidably received within the through-aperture and carried by a first flanged portion and a second flanged portion extending toward the lift pin axis defined by the lift pin body.

In addition to one or more of the features described above, or as an alternative, further examples may include that the through-aperture has a first through-aperture segment and a second through-aperture segment separated by a plurality of flanges, that the first through-aperture segment couples an upper surface of the weight body to the plurality of flanges, and that the second through-aperture segment couples the plurality of flanges to the lower surface of the weight body.

In addition to one or more of the features described above, or as an alternative, further examples may include that the first through-aperture segment has a generally circular shape between the upper surface and the plurality of flanges, and that the second through-aperture has a generally cruciform shape extending between the lower surface and the plurality of flanges.

In addition to one or more of the features described above, or as an alternative, further examples may include that the first-through aperture segment has a diameter that is substantially equivalent to a width of the stem segment of the lift pin body, that the second through-aperture segment has a second segment major width that is greater that a major width the span feature of the lift pin body, and that the second through-aperture segment has a second segment minor width that is less than the major width of the span feature of the lift pin body.

In addition to one or more of the features described above, or as an alternative, further examples may include that the lift pin weight has a frustoconical shape, that the first through-aperture segment has a diameter that is substantially equivalent to a width of the stem segment of the lift pin body, and that the second through-aperture segment has a width that is substantially equivalent to a width of the span feature of the lift pin body.

A semiconductor processing system is provided. The semiconductor processing system includes a chamber body formed from a quartz material, a substrate support arranged within an interior of the chamber body and configured to support a substrate during deposition of a material layer onto the substrate, a lift pin as described above, and lift pin weight with a through-aperture. The lift pin is slidably received within a lift pin aperture extending through the substrate support and a portion of the stem segment and the span feature of the lift pin are arranged within the through-aperture such that the lift pin weight is carried by the lift pin through the span feature and neck segment of the lift pin body.

In addition to one or more of the features described above, or as an alternative, further examples may include that the lift pin body of the lift pin is formed from silicon carbide, and that the weight body of the lift pin weight is formed from quartz.

A method of making a lift pin arrangement for a semiconductor processing system is provided. The method includes, at a lift pin as described above, arranging a lift pin weight with a weight body defining a through-aperture therethrough along the lift pin axis and rotating the weight body about the lift pin axis such that a flanged portion major width is registered to the major width of the span feature of the lift pin body. The weight body of the lift pin weight is translated along the lift pin axis such that the span feature of the lift pin body is axially between the contact pad of the lift pin body and the span feature of the lift pin body, and the weight body is rotated about the lift pin axis such that a first flange portion and a second flange portion of the weight body overlay the major width of the span feature of the lift pin body. The weight body is then translated along the lift pin axis in a direction opposite the contact pad such that the first flange portion and the second flange portion of the weight body both abut the span feature of the lift pin body such that the lift pin weight is carried by the span feature of the lift pin body to exert downward force on the lift pin during movement of the lift pin through a substrate support within a chamber arrangement of as semiconductor processing system.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system including a lift pin arrangement in accordance with the present disclosure, showing the lift pin arrangement supported within a chamber arrangement of the semiconductor processing system;

FIG. 2 is a cross-sectional side view of the chamber arrangement of the semiconductor processing system of FIG. 1 according to a first example of the present disclosure, showing a lift pin arrangement including a lift pin and a lift pin weight carried by a substrate support during rotation of about a rotation axis within the chamber arrangement;

FIGS. 3-5 are views of the chamber arrangement of FIG. 2, sequentially showing the lift pin arrangement seating and unseating a substrate from the substrate support prior to and subsequent to deposition of a material layer onto the substrate;

FIG. 6 is a side view of the lift pin arrangement of FIG. 1 according to an example of the present disclosure, showing the lift pin exploded away from the lift pin weight along a lift pin axis according to the example;

FIGS. 7-9 are side and bottom views of a portion of the lift pin of FIG. 6 according to an example of the present disclosure, showing facets defined on a span feature of the lift pin for supporting the lift pin weight on the lift pin;

FIGS. 10-12 are sectional, top plan and bottom views of the lift pin weight of FIG. 6 according to an example of the present disclosure, showing a through-aperture extending through the lift pin weight and ledge arrangement for supporting the lift pin weight on the lift pin;

FIGS. 13-16 are cross-sectional side views of the lift pin and lift pin weight of FIG. 7 according to an example of the present disclosure, sequentially showing the lift pin weight being assembled onto the lift pin according to the example; and

FIG. 17 is a block diagram of a method of making a lift pin arrangement, showing operations of the method according to an illustrative and non-limiting examples of the method.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

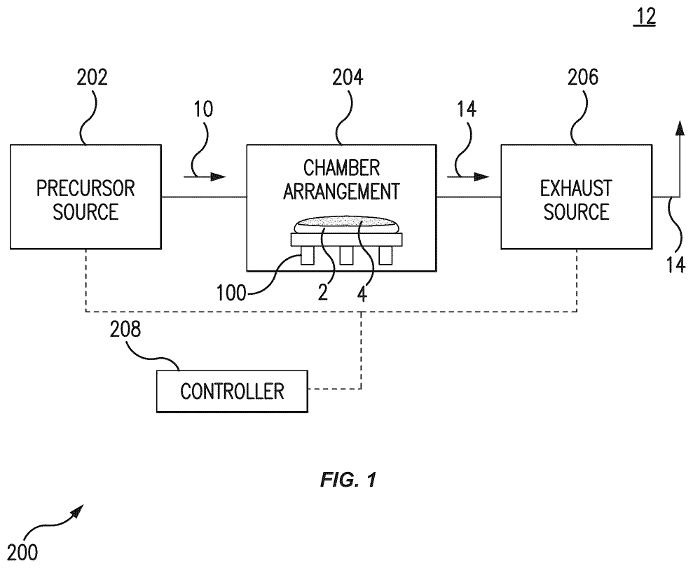

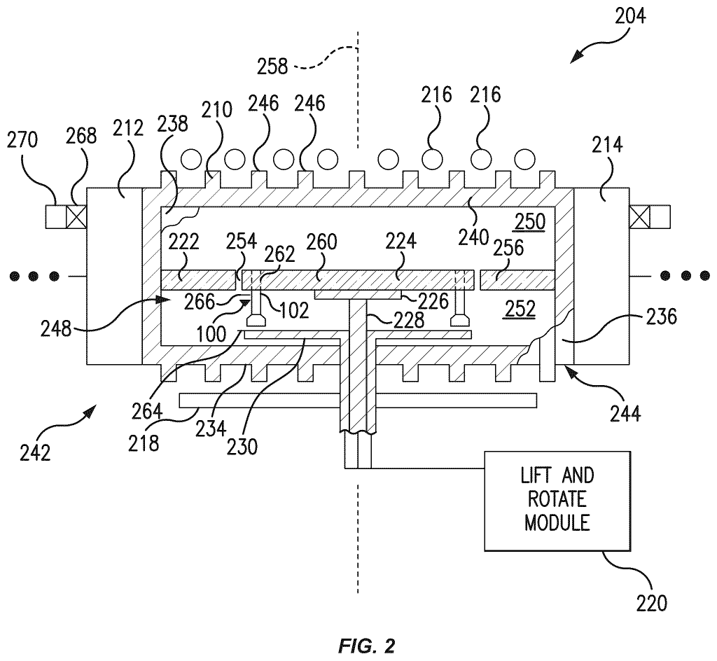

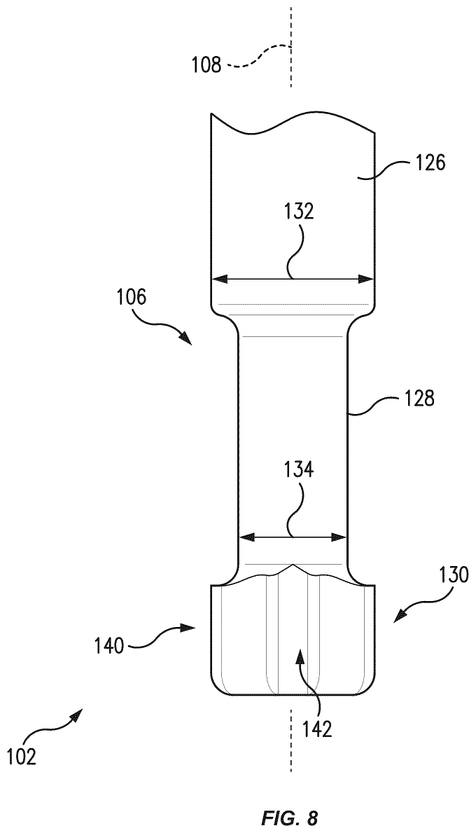

Reference will now be made to the drawings wherein like reference numerals identify similar structural features or aspects of the subject disclosure. For purposes of explanation and illustration, and not limitation, a partial view of a lift pin arrangement including a lift pin in accordance with the present disclosure is shown in FIG. 1 and is designated generally by reference character 100. Other examples of lift pins, lift pin arrangements, semiconductor processing systems including lift pin arrangements, and methods of making lift pin arrangements for semiconductor processing systems in accordance with the present disclosure, or aspects thereof, are provided in FIGS. 2-17, as will be described. The lift pins and lift pin arrangements of the present disclosure may be used to seat and unseat substrates from substrate supports in semiconductor processing systems employed to deposit material layers onto substrates using chemical vapor deposition techniques, such as in semiconductor processing systems having rotating and fixed substrate supports where material may accrete within mechanical clearances defined between the lift pins employed to seat substrates on the substrate support and the substrate support employed to support the substrates during deposition, though the present disclosure is not limited to any particular type of substrate support or deposition technique.

Referring to FIG. 1, a semiconductor processing system 200 including the lift pin arrangement 100 is shown according to an example of the present disclosure. In the illustrated example the semiconductor processing system 200 includes a precursor source 202, a chamber arrangement 204, an exhaust source 206, and controller 208. The precursor source 202 includes a material layer precursor 10 and is configured to provide a flow of the material layer precursor 10 to the chamber arrangement 204. The chamber arrangement 204 is connected to the exhaust source 206 and is configured to deposit a material layer 4 onto the substrate 2 using the flow of the material layer precursor 10 received from the precursor source 202. The exhaust source 206 is fluidly coupled to an external environment 12 outside of the chamber arrangement 204 and is configured to communicate a flow of residual material layer precursor and/or reaction products 14 issued by the chamber arrangement 204 to the external environment 12, and may include one or more vacuum pump and/or an abatement apparatus. The controller 208 is operably connected to the chamber arrangement 204, for example, to seat the substrate 2 within the chamber arrangement 204 prior to deposition of the material layer 4 onto the substrate 2 and unseat the substrate 2 subsequent to deposition of the material layer 4 onto the substrate 2.

In certain examples the material layer precursor 10 may include a silicon-containing material layer precursor. Examples of suitable silicon-containing material layer precursors include silane (SiH₄), dichlorosilane (H₂SiCl₂), and disilane (Si₂H₆). In accordance with certain examples, the material layer precursor 10 may include a germanium-containing material layer precursor, such as germane (GeH₄). It is contemplated that that the material layer precursor 10 may include a dopant-containing material layer precursor, such as an n-type dopant or a p-type dopant. Non-limiting examples of suitable n-type dopants include arsine (AsH₃); non-limiting examples of suitable p-type dopants include diborane (B₂H₆) and phosphine (PH₃). It is also contemplated that, in accordance with certain examples the material layer precursor 10 may include a carrier/purge gas like hydrogen (H₂) gas and/or an etchant source including an etchant like hydrochloric acid (HCl) and remain within the scope of the present disclosure.

With reference to FIG. 2, the chamber arrangement 204 is shown according to an example of the present disclosure. In the illustrated example the chamber arrangement 204 includes a chamber body 210, an injection flange 212, an exhaust flange 214, an upper heater element array 216, a lower heater element array 218, and a lift and rotate module 220. The chamber arrangement 204 also includes a divider 222, a substrate support 224, a support member 226, a shaft member 228, a lift pin actuator 230, and the lift pin arrangement 100. Although shown and described herein as including certain elements and having a specific arrangement, i.e., a single-wafer crossflow arrangement with a rotating substrate support 224, it is to be understood and appreciated that the chamber arrangement 204 may include other elements and/or exclude elements shown and described herein, and/or having as well as have another arrangement in other examples and remain within the scope of the present disclosure.

The chamber body 210 extends longitudinally between an injection end 242 and a longitudinally opposite exhaust end 244. The injection flange 212 abuts the injection end 242 of the chamber body 210 and couples the precursor source 202 to the chamber body 210 to communicate the material layer precursor 10 to an interior 248 of the chamber body 210. The exhaust flange 214 abuts the exhaust end 244 of the chamber body 210 and couples the chamber body 210 to communicate the residual precursor and/or reaction products 14 issued by the chamber arrangement 204 to the exhaust source 206. It is contemplated that the chamber body 210 have an upper wall 232, a lower wall 234, a first sidewall 236, and a second sidewall 238. The upper wall 232 longitudinally spans the injection end 242 and the exhaust end 244 of the chamber body 210. The lower wall 234 is similar to the upper wall 232 and is additionally spaced apart from the upper wall 232 by the interior 248 of the chamber body 210. The first sidewall 236 and the second sidewall 238 coupled the lower wall 234 to the upper wall 232, and are laterally spaced apart from one another by the interior 248 of the chamber body 210. It contemplated that the chamber body 210 be formed from a transparent material 240, e.g., a material transmissive to electromagnetic radiation within an infrared waveband, such as a ceramic material like quartz or sapphire. It is contemplated that the chamber body 210 may have a plurality of exterior ribs 246 extending about an exterior surface of the chamber body 210 and longitudinally spaced apart from one another between the injection end 242 and the exhaust end 244 of the chamber body 210. As shown and described herein the upper wall 232 and the lower wall 234 are substantially planar in shape. As will be appreciated by those of skill in the art in view of the present disclosure, either (or both) the upper wall 232 and the lower wall 234 may have an arcuate profile and/or a domelike shape and remain within the scope of the present disclosure.

The upper heater element array 216 is configured to communicate radiant heat into the interior 248 of the chamber body 210, e.g., using electromagnetic radiation within an infrared waveband, and in this respect is supported above the chamber body 210. It is contemplated that the upper heater element array 216 include a plurality of heater elements, e.g., linear filament-type lamps, extending laterally between the first sidewall 236 and the second sidewall 238 of the chamber body 210 and longitudinally spaced apart from one another between the injection end 242 and the exhaust end 244 of the chamber body 210. The lower heater element array 218 is similar to the upper heater element array 216, is additionally supported below the lower wall 234 of the chamber body 210, and may further include a plurality of linear filament-type lamps extending longitudinally between the injection end 242 and the exhaust end 244 of the chamber body 210 and laterally spaced apart from one another between the first sidewall 236 and the second sidewall 238. Although shown and described herein as including linear lamps having a specific orientation it is to be understood and appreciated that either (or both) the upper heater element array 216 and the lower heater element array 218 may have linear filament-type lamps with different orientation, and/or include bulb-type lamps, and remain within the scope of the present disclosure.

The divider 222 is fixed within an interior 248 of the chamber body 210 and divides the interior 248 into an upper chamber 250 and a lower chamber 252. It is contemplated that the divider 222 be further formed from an opaque material 256, e.g., a material opaque to electromagnetic radiation within an infrared waveband, and that divider 222 further define therethrough a divider aperture 254. It is contemplated that the divider aperture 254 fluidly couples the upper chamber 250 of the chamber body 210 to the lower chamber 252 of the chamber body 210, and that the substrate support 224 be supported for rotation R about a rotation axis 258 within the interior 248 of the chamber body 210 and at least partially within the divider aperture 254. In certain examples the opaque material 256 may include a carbonaceous material, such as graphite and/or pyrolytic carbon. In accordance with certain examples, the opaque material 256 may include a ceramic material, such as silicon carbide, the ceramic material coating an underlying bulk carbonaceous material or forming a bulk material defining the divider 222.

The substrate support 224 is configured to seat the substrate 2 during deposition of the material layer 4 onto the substrate 2 and in this is supported within the divider aperture 254 for rotation about a rotation axis 258. It is contemplated that the substrate support 224 may be formed from an opaque material 260, which may be similar may or differ in composition from that of the opaque material 256 forming the divider 222. It is also contemplated that the substrate support 224 may include a susceptor structure, and that the substrate support 224 may be fixed in rotation R about the rotation axis 258 relative to the support member 226. In this respect it is contemplated that the support member 226 be arranged within the lower chamber 252 of the chamber body 210 and along the rotation axis 258, that the support member 226 couple the substrate support 224 to the shaft member 228, and that the shaft member 228 extend through the lower wall 234 of the chamber body 210 and operably couple the lift and rotate module 220 to the substrate support 224 such that the lift and rotate module 220 may rotate the substrate support 224 about the rotation axis 258 during deposition of the material layer 4 onto the substrate 2.

It is contemplated that the substrate support 224 define therethrough one or more lift pin aperture 262, and that a lift pin 102 of the lift pin arrangement 100 be slidably received within the lift pin aperture 262. It is further contemplated that the lift pin actuator 230 be arranged (at least in part) within the lower chamber 252 of the chamber body 210, e.g., about the shaft member 228, and also extend through the lower wall 234 of the chamber body 210. The lift pin actuator 230 is operably associated with the lift and rotate module 220 for movement between a first position 264 and a second position 266 to seat and unseat substrates, e.g., the substrate 2, from the substrate support 224. When in the first position 264 the lift pin arrangement 100 dangles from the substrate support 224, the lift pin arrangement 100 spaced apart from the lift pin actuator 230 and carried by the substrate support 224 during rotation about the rotation axis 258. When in the second position 266 the lift pin actuator 230 abuts the lift pin arrangement 100 such that the lift pin 102 protrudes above the substrate support 224. As will be appreciated by those of skill in the art in view of the present disclosure, movement between the first position 264 and the second position 266 seats and unseats the substrate 2 from the substrate support 224. As will also be appreciated by those of skill in the art in view of the present disclosure, movement between the first position 264 and the second position 266 also enables loading and unloading of substrates from the chamber body 210, for example, using a substrate transfer robot 270 with an end effector 272 coupled to the chamber body 210 by a gate valve 268. As shown and described herein the chamber arrangement 204 includes three (3) lift pin arrangements 100, it is to be understood and appreciated that the chamber arrangement 204 may have fewer or additional lift pin arrangements 100 in other examples and remain within the scope of the present disclosure.

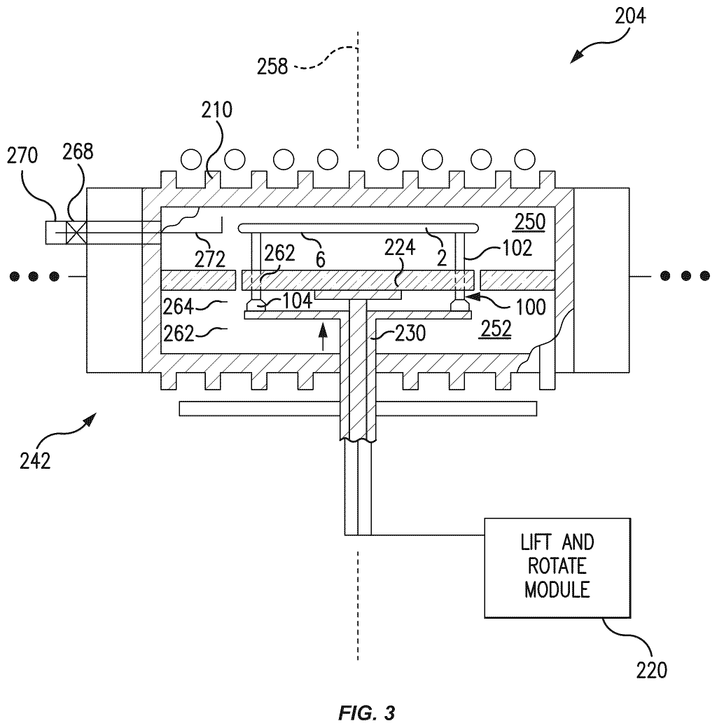

With reference to FIGS. 3-5, seating and unseating of the substrate 2 using the lift pin arrangement 100 is shown. As shown in FIG. 3, seating of the substrate 2 within the chamber body 210 is accomplished by opening the gate valve 268 and advancing the end effector 272 into the upper chamber 250 of the chamber body 210 using the substrate transfer robot 270 such that the substrate 2 is in registration with the substrate support 224 at a location above the substrate support 224. The lift and rotate module 220 then translates the lift pin actuator 230 along the rotation axis 258 toward the substrate support 224 between the first position 264 and the second position 266. As the lift pin actuator 230 translates along the rotation axis 258 the lift pin actuator 230 comes into abutment with a lift pin weight 104 supported on the lift pin 102, further translation of the lift pin actuator 230 thereafter driving the lift pin 102 through the substrate support 224 such that the lift pin 102 protrudes above the substrate support 224 and advances upwards within the upper chamber 250 of the chamber body 210.

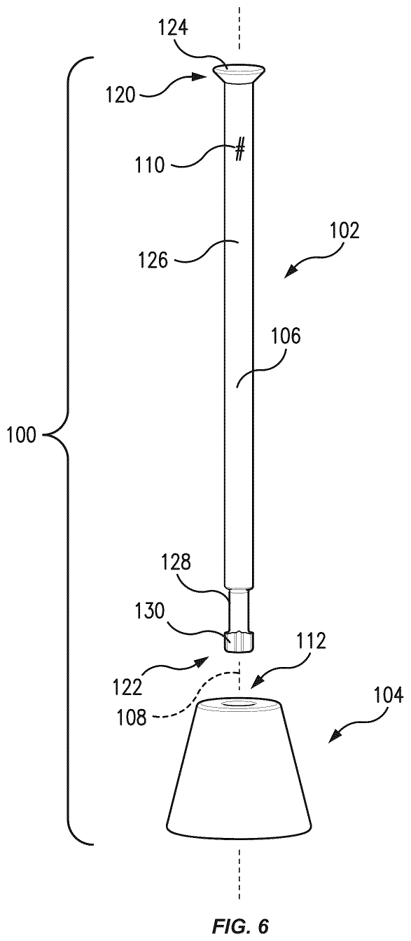

Advancement of the lift pin 102 continues until the lift pin 102 comes into abutment with a lower surface 6 of the substrate 2, subsequent advancement thereafter transferring the substrate 2 to the lift pin arrangement 100. The substrate transfer robot 270 then withdraws the end effector 272 from the upper chamber 250 of the chamber body 210 and lift and rotate module 220 translates the lift pin actuator 230 downwards within the lower chamber 252 of the chamber body 210 between the second position 266 and the first position 264 of the lift pin actuator 230. The downward translation of the lift pin actuator 230 withdraws support from the lift pin arrangement 100, the lift pin 102 sliding downward through the lift pin aperture 262 by operation of gravity upon mass of the lift pin weight 104 as well as that of the lift pin 102 and the substrate 2. Downward sliding of the lift pin 102 through the lift pin aperture 262 continues until a contact pad 124 (shown in FIG. 6) of the lift pin 102 seats within the lift pin aperture 262, further downward translation of the lift pin actuator 230 causing the lift pin arrangement 100 to dangle from the substrate support 224 within the lower chamber 252 of the chamber body 210.

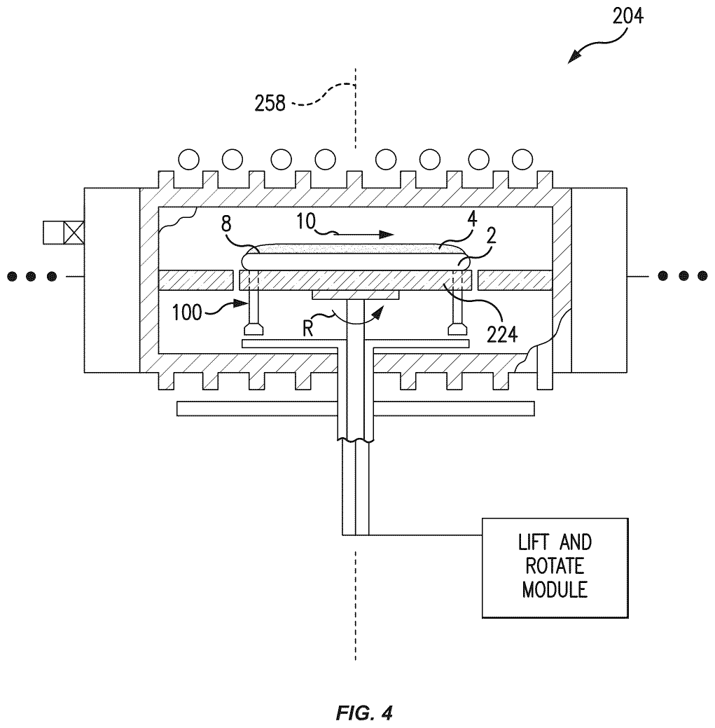

As shown in FIG. 4, deposition of the material layer 4 is accomplished by heating the substrate 2 to a predetermined material layer deposition temperature, rotating R the substrate support 224 and thereby by the substrate 2 about the rotation axis 258, and exposing the substrate 2 to the material layer precursor 10 under conditions whereby the material layer 4 deposits onto the substrate 2. Once the material layer 4 reaches a predetermined material layer thickness, flow of the material layer precursor 10 to the interior 248 of the chamber body 210 ceases. The substrate 2 may then be permitted to cool, e.g., to a substrate unload temperature, either by allowing the substrate 2 to remain seated on the substrate support 224 and/or by unseating the substrate 2 from the substrate support 224 using the lift pin arrangement 100 and the lift pin actuator 230. As will be appreciated by those of skill in the art in view of the present disclosure, the lift pin arrangement 100 is carried by the substrate support 224 during the rotation R about the rotation axis 258, the lift pin arrangement 100 thereby rotating R in concert with the substrate support 224 about the rotation axis 258 during deposition of the material layer 4 onto an upper surface 8 of the substrate 2.

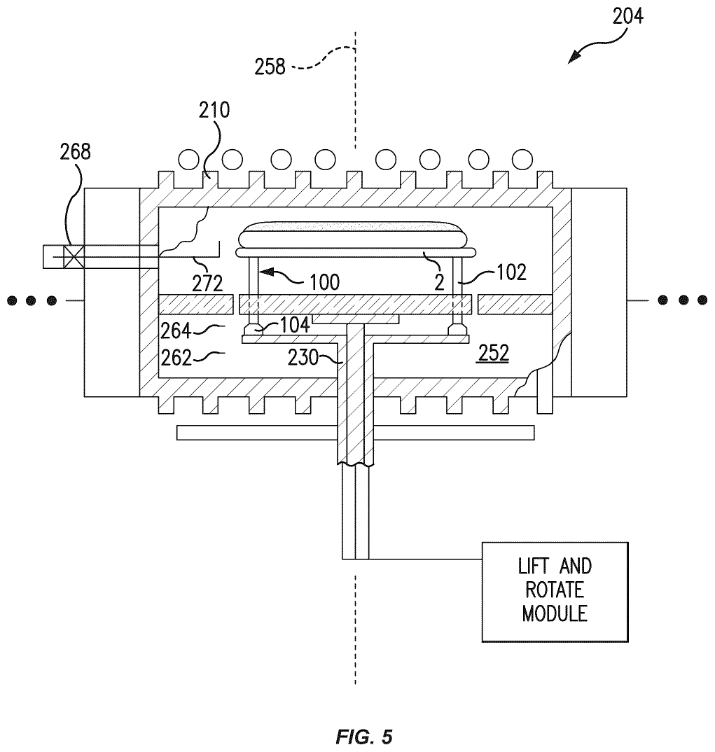

As shown in FIG. 5, unseating of the substrate 2 is accomplished by registering the lift pin actuator 230 with the lift pin arrangement 100 in rotation about the rotation axis 258 such that the lift pin arrangement 100 overlays the lift pin actuator 230. The lift pin actuator 230 is next driven upwards within the lower chamber 252 of the chamber body 210 toward the substrate support 224 between the first position 264 and the second position 266 using the lift and rotate module 220. Upward translation of the lift pin actuator 230 along the rotation axis 258 toward the substrate support 224 causes the lift pin actuator 230 to come into abutment with the lift pin weight 104 within the lower chamber 252 of the chamber body 210, further upward translation thereafter causing the lift pin 102 to slide upwards through the lift pin aperture 262 such that the lift pin 102 protrudes from the substrate support 224. Protrusion of the lift pin 102 above the substrate support 224 unseats the substrate 2 from the substrate support 224 and transfers the substrate 2 to the lift pin arrangement 100, further translation of the lift pin actuator 230 thereafter causing the substrate 2 to be supported at a location above the substrate support 224 along the rotation axis 258 and within the upper chamber 250 of the chamber body 210.

Once the lift pin actuator 230 reaches the second position 266, and the substrate 2 supported above the substrate support 224, the gate valve 268 is again opened and the end effector 272 advanced into the upper chamber 250 of the chamber body 210 by the substrate transfer robot 270. It is contemplated that the substrate transfer robot 270 advance the end effector 272 such that the end effector 272 is vertically between the substrate 2 and the substrate support 224. So positioned the lift pin actuator 230 is again translated downward within the lower chamber 252 of the chamber body 210 from the second position 266 toward the first position 264 of the lift pin actuator 230. Downward translation of the lift pin actuator 230 causes the lift pin arrangement 100, and more specifically the lift pin 102, to slide downward through the lift pin aperture 262 and retreat in the generally direction of the substrate support 224. It is contemplated that the retreat be such that the substrate 2 transfer from the lift pin 102 to the end effector 272, and that that the substrate transfer robot 270 thereafter withdraw the end effector 272 and the substrate 2 carried by the end effector 272 from the upper chamber 250 of the chamber body 210. The substrate 2 may then be sent on for further processing and the chamber arrangement 204 prepared for deposition of a further material layer onto another substrate, or the a further layer onto the substrate 2, as appropriate for the semiconductor device being fabricated using the material layer 4.

As has been explained above, lift pins may bind within a substrate support during seating and/or unseating of a substrate on the substrate. Binding may occur, for example, due to tilt of the lift pin within the substrate support. Binding may also occur due material accretion on the lift pin and/or within the lift pin aperture within which the lift pin is received, such as when residual precursor and/or reaction product infiltrates the atmosphere containing the lift pin during material layer deposition, accretes onto the lift pin, and is thereafter carried into the lift pin aperture during sliding of the lift pin through the lift pin aperture. To limit (or eliminate entirely) such binding, the lift pin arrangement 100 is provided.

With reference to FIGS. 6-12 the lift pin arrangement 100 is shown according to an example of the present disclosure. As shown in FIG. 6, the lift pin arrangement 100 generally includes the lift pin 102 and the lift pin weight 104. The lift pin 102 includes a lift pin body 106. The lift pin body 106 defines (or is arranged along) a lift pin axis 108 and is configured to be slidably received within the lift pin aperture 262 (shown in FIG. 2) extending through the substrate support 224 (shown in FIG. 2). The lift pin body 106 is further configured to carry (e.g., support) the lift pin weight 104 during deposition of the material layer 4 (shown in FIG. 1) onto the substrate 2 (shown in FIG. 1), the lift pin weight 104 thereby exerting a tensile load upon the lift pin body 106. The lift pin body 106 may be formed from an opaque ceramic material 110, for example a material opaque to electromagnetic radiation within an infrared waveband, and may have a heat transfer coefficient substantially equivalent to that of the material forming the substrate support 224. Examples of suitable opaque materials include ceramic materials, such as silicon carbide, as well as carbonaceous materials such as glassy carbon. As will be appreciated by those of skill in the art in view of the present disclosure, forming the lift pin body 106 from an opaque ceramic material may limit temperature variation across the substrate 2, promoting uniformity of the material layer 4. Advantageously, weighting the lift pin 102 with the lift pin weight 104 tends to both (a) center the lift pin body 106 within the lift pin aperture 262 such that the lift pin axis 108 remains parallel to the rotation axis 258 (shown in FIG. 2) as well as (b) promote seating of the lift pin 102 within the substrate support 224 (shown in FIG. 1), for example by opposing horizontal force components exerted on the lift pin body 106 by the substrate 2 and/or by increasing downward force on the lift pin body 106 during withdrawal of the lift pin actuator 230 (shown in FIG. 2).

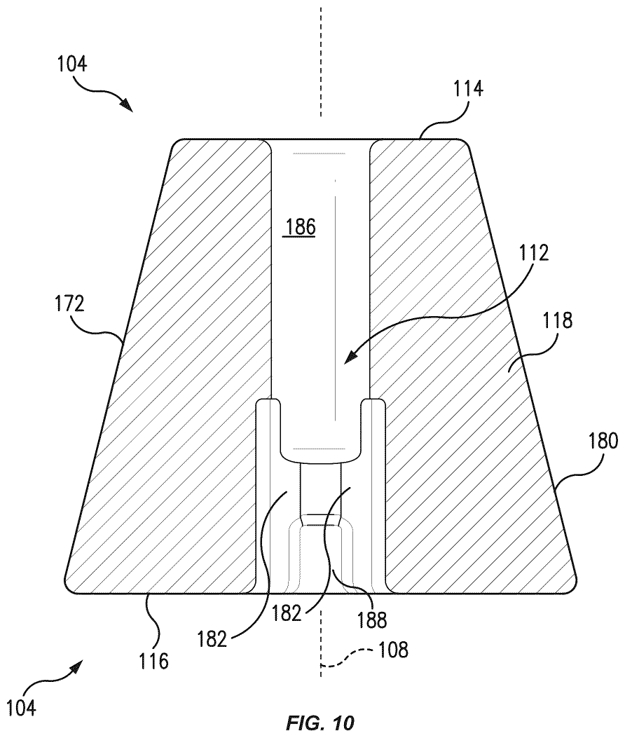

The lift pin weight 104 is configured to be carried by the lift pin body 106 and in this respect defines a through-aperture 112. The through-aperture 112 extends through the lift pin weight 104, e.g., between an upper surface 114 (shown in FIG. 10) and a lower surface 116 (shown in FIG. 10) of the lift pin weight 104, and is sized to receive therein (in part) the lift pin body 106. It is contemplated that the lift pin weight 104 be formed from a transparent material 118 (shown in FIG. 10), such as a material transmissive to electromagnetic radiation within an infrared waveband. Examples of suitable transmissive materials include ceramic materials, such as quartz and fused silica by way of non-limiting examples. As will also be appreciated by those of skill in the art in view of the present disclosure, forming the lift pin weight 104 from the transparent material 118 may limit shading of an underside of the substrate support 224 (shown in FIG. 1) from electromagnetic radiation emitted by the lower heater element array 218 (shown in FIG. 1), also limiting temperature variation across the substrate 2 and also promoting uniformity of the material layer 4.

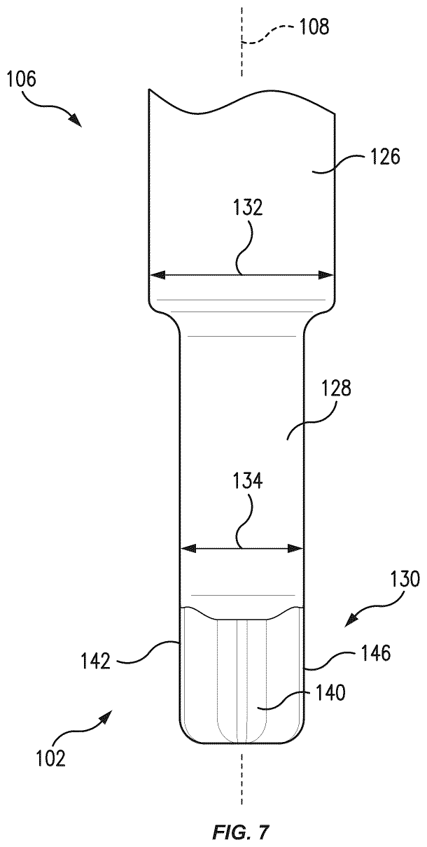

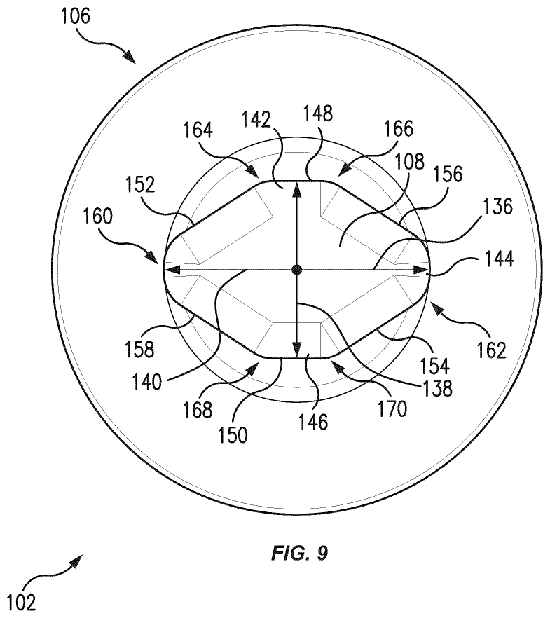

In certain examples of the present disclosure the lift pin body 106 may extend axially between a first end 120 and an axially opposite second end 122, and may further have a stem segment 126, a neck segment 128 and a span feature 130. The contact pad 124 may be defined at the first end 120 of the lift pin body 106 and configured to seat and unseat the substrate 2 (shown in FIG. 1) from the substrate support 224 (shown in FIG. 2). The stem segment 126 may extend axially from the contact pad 124, have a stem diameter 132 (shown in FIG. 7), and couple the neck segment 128 and the span feature 130 to the contact pad 124. The neck segment 128 may extend from the stem segment 126, have a neck diameter 134 (shown in FIG. 7), and couple the span feature 130 to the stem segment 126 of the lift pin body 106. The span feature 130 may be defined at a second end 122 of the lift pin body 106, be connected to the contact pad 124 by the neck segment 128 and the stem segment 126 of the lift pin body 106, and have a minor width 138 (shown in FIG. 9) and a major width 136 (shown in FIG. 9). The minor width 138 of the span feature 130 may be substantially equivalent to a neck diameter 134 (shown in FIG. 7) defined by the neck segment 128 of the lift pin body 106, the major width 136 of the span feature 130 may be greater than the minor width 138 of the span feature 130, and the major width 136 of the span feature 130 may further be greater than a stem diameter 132 (shown in FIG. 7) defined by the neck segment 128 of the lift pin body 106 to suspend the lift pin weight 104 from the lift pin body 106. In certain examples the major width 136 may be offset form the minor width 138 by about 90 degrees about the lift pin axis 108, the minor width 138 substantially orthogonal to the major width 136 in such examples. In accordance with certain examples, the major width 136 may intersect the minor width 138, such as at an intersection point of the major width 136 and the minor width 138. It is also contemplated that the major width 136 may be axially offset from the minor width 138 and remain within the scope of the present disclosure.

As shown in FIGS. 7-9, the span feature 130 may have both a major lobe 140 and a minor lobe 142. The major lobe 140 may be circumferentially offset from the minor lobe 142, for example by between about 90 degrees and about 270 degrees about the lift pin axis 108, and may be spanned by the major width 136 of the span feature 130. The major lobe 140 may further laterally protrude from the lift pin body 106, for example in direction substantially orthogonal relative to the lift pin axis 108, and may have axial height that is less than an axial height of the neck segment 128 of the lift pin body 106. It is contemplated that the major lobe 140 protrude laterally from the lift pin body 106, for example by a distance substantially greater than one-half the neck diameter 134 defined by the neck segment 128. It is further contemplated that the major lobe 140 may protrude laterally from the lift pin body 106 by a distance substantially equivalent to about one-half the stem diameter 132 defined by the stem segment 126 of the lift pin body 106.

In certain examples, the major lobe 140 may be a first major lobe 140 and the span feature 130 may have one or more second major lobe 144. The second major lobe 144 may be similar to the first major lobe 140 in such examples, the one or more second major lobe 144 additionally circumferentially offset from the first major lobe 140 about the lift pin axis 108, the one or more second major lobe 144 further circumferentially offset from the minor lobe 142 about the lift pin axis 108. In this respect the one or more second major lobe 144 may be separated (e.g., circumferentially separated) from the first major lobe 140 by the minor lobe 142. For example, the one or more second major lobe 144 may be circumferentially offset form the minor lobe 142 by about 90 degrees about the lift pin axis 108, and the one or more second major lobe 144 may be circumferentially offset from the first major lobe 140 by about 180 degrees about the lift pin axis 108. Although shown and described herein as having two (2) major lobes, it is to be understood and appreciated that the span feature 130 may have a single major lobe or more than two (2) major lobes and remain within the scope of the present disclosure.

The minor lobe 142 may be circumferentially intermediate the first major lobe 140 and the second major lobe 144, the minor lobe 142 offset from either (or both) the first major lobe 140 and the one or more second minor lobe 146 by about 90 degrees about the lift pin axis 108. The minor lobe 142 may further protrude from the lift pin body 106, for example in a direction substantially orthogonal relative to the lift pin axis 108, and is this respect it is contemplated that the minor lobe 142 extend radially from the lift pin body 106 by a radial distance that is less than a radial distance from which the major lobe 140 radially protrudes from the lift pin body 106. In further respect, the minor lobe 142 may radially protrude from the lift pin body 106 by a radial distance that is less than about one-half the neck diameter 134 defined by the neck segment 128 of the lift pin body 106, may have an axial height that is greater than an axial height of the major lobe 140 and less than an axial height of the neck segment 128 of the lift pin body 106, and may be spanned by the minor width 138 of the span feature 130.

In certain examples the minor lobe 142 maybe a first minor lobe 142 and the span feature 130 may have one or more second minor lobe 146. The one or more second minor lobe 146 may be similar to the first minor lobe 142, additionally be circumferentially offset from the first minor lobe 142, and further be circumferentially intermediate the first major lobe 140 and the second major lobe 144. For example, the one or more second major lobe 144 may be circumferentially offset from either (or both) the first minor lobe 142 and/or the one or more second minor lobe 146 by about 90 degrees about the lift pin axis 108. In this respect the one or more second minor lobe 146 may be separated (e.g., circumferentially separated) from the first minor lobe 142 by the major lobe 140. The one or more second minor lobe 146 may be further circumferentially offset from the first minor lobe 142 by about 180 degrees about the lift pin axis 108. Although shown and described herein as having two (2) minor lobes, it is to be understood and appreciated that the span feature 130 may have a single minor lobe or more than two (2) minor lobes and remain within the scope of the present disclosure.

Referring to FIG. 9, the span feature 130 may have (e.g., be bounded by) a plurality of facets. In this respect the span feature 130 may have (or be bounded by) a first planar facet 148 and one or more second planar facet 150. The minor width 138 may intersect both (e.g., extend between) the first planar facet 148 and the one or more second planar facet 150. The one or more second planar facet 150 may be offset from the first planar facet 148 by about 180 degrees about the lift pin axis 108. In further respect either (or both) the first planar facet 148 and the one or more second planar facet 150 may be substantially orthogonal relative to the minor width 138. In certain examples the span feature 130 may have (e.g., be bounded by) one or more intermediate planar facet 152. The one or intermediate planar facet 152 may be intermediate (e.g., offset from both) the minor width 138 and the major width 136, for example circumferentially offset from either (or both) the minor width 138 and the major width 136 about the lift pin axis 108. In accordance with certain examples, the one or more intermediate planar facet 152 may be intermediate the first planar facet 148 and the one or more second planar facet 150, the or more intermediate planar facet 152 circumferentially spacing the first planar facet 148 from the one or more second planar facet 150 in this respect.

In certain examples the span feature 130 may have (e.g., be bounded by) six (6) planar facets. In this respect it is contemplated that the one or more intermediate planar facet 152 may be a first intermediate planar facet 152 and the span feature 130 may have (or be bounded by) a second intermediate planar facet 154, a third intermediate planar facet 156, and a fourth intermediate planar facet 158 each intermediate the minor width 138 and the major width 136 of the span feature 130. The second intermediate planar facet 154 may be similar to the first intermediate planar facet 152, additionally be separated from the first intermediate planar facet 152 by the both the major width 136 and the minor width 138, and further extend substantially in parallel with the first intermediate planar facet 152. The third intermediate planar facet 156 may be also be similar to the first intermediate planar facet 152, additionally be separated from the first intermediate planar facet 152 by only the minor width 138, and further be oblique to both the first intermediate planar facet 152 and the second intermediate planar facet 154. The fourth intermediate planar facet 158 may be separate the first intermediate planar facet 152 form the second planar facet 150 and extend substantially in parallel with the third intermediate planar facet 156, the plurality of facets thereby imparting a generally rhomboidal shape to the span feature 130. Although shown and described here as having six (6) planar facets, it is to be understood and appreciated that the span feature 130 may have (or be bounded by) fewer or additional planar facets and remain within the scope of the present disclosure.

In certain examples the span feature 130 may have (e.g., be bounded by) a plurality of arcuate facets. In this respect the span feature 130 may have (or be bounded by) a first terminal arcuate facet 160 and one or more second terminal arcuate facet 162. The first arcuate facet 160a and the one or more second terminal arcuate facet 162 may be on laterally opposite ends of the major width 136. The one or more second terminal arcuate facet 162 may be offset from the first terminal arcuate facet 160 by about 180 degrees about the lift pin axis 108. The one or more second terminal arcuate facet 162 may further be separated from first terminal arcuate facet 160 by both the first planar facet 148 and the one or more second planar facet 150. It is also contemplated that the one or more second terminal arcuate facet 162 may be separated from the first terminal arcuate facet 160 by the minor width 138, and that each of the intermediate planar facets 152-158 may separate the one or more second terminal arcuate facet 162 from the first terminal arcuate facet 160.

In accordance with certain examples, the span feature 130 may have (or be bounded by) a plurality of intermediate arcuate facets. In this respect it is contemplated that the span feature 130 may have a first intermediate arcuate facet 164, a second intermediate arcuate facet 166, a third intermediate arcuate facet 168, and a fourth intermediate arcuate facet 170. The first intermediate arcuate facet 164 and the second intermediate arcuate facet 166 may be circumferentially between the first terminal arcuate facet 160 and the second terminal arcuate facet 162, further separated from one another by the minor width 138, and on common lateral side of the major with 140 such that two or more of the plurality of arcuate facets are defined between the major width 136 and the minor width 138 of the span feature 130. The third intermediate arcuate facet 168 and the fourth intermediate arcuate facet 170 may be similar to the first intermediate arcuate facet 164 and the second intermediate arcuate facet 166, and further separated therefrom by the major width 136. It is contemplated that the second intermediate arcuate facet 166 may be coupled to the first intermediate arcuate facet 164 by the first planar facet 148, that the third intermediate arcuate facet 168 may be coupled to the fourth intermediate arcuate facet 170 by the second planar facet 150, that the first terminal arcuate facet 160 may couple the first intermediate arcuate facet 164 to the third intermediate arcuate facet 168, and that the second terminal arcuate facet 162 may couple the second intermediate arcuate facet 166 to the fourth intermediate arcuate facet 170. As will be appreciated by those of skill in the art in view of the present disclosure, plurality of arcuate facets may limit stress within the material forming the span feature 130, enabling the lift pin body 106 to support a lift pin weight 104 having greater weight (and associated tensile load) than otherwise possible for a given with of the neck diameter 134. Although shown and described herein as having eight (8) arcuate facets, it is to be understood and appreciated that the span feature 130 may have (or be bounded by) fewer or additional arcuate facets and remain within the scope of the present disclosure.

With reference to FIGS. 10-13, the lift pin weight 104 is shown. The lift pin weight 104 includes a weight body 172 having a mass selected to resist opposition to movement between the first position 264 (shown in FIG. 2) and the second position 266 (shown in FIG. 2), for example due to accreted material on the lift pin 102 (shown in FIG. 2) and/or within the lift pin aperture 262 (shown in FIG. 2). In certain examples, the weight body 172 may be formed from a transparent material 118, e.g., a material transmissive to electromagnetic radiation within an infrared waveband, such as a ceramic material like quartz or fused silica. In accordance with certain examples, the weight body 172 may have a frustoconical shape. In this respect it is contemplated that the weight body 172 have an upper surface 114 extending circumferentially about the lift pin axis 108, a lower surface 116 extending circumferentially about the lift pin axis 108 and axially offset from the upper surface 114 along the lift pin axis 108, and a lateral surface 180 coupling the lower surface 116 to the upper surface 114 and diametrically tapering between the lower surface 116 and the upper surface 114 of the weight body 172.

The lift pin weight 104 be configured to slidably receive therein the lift pin 102 (shown in FIG. 2) and in this respect has a through-aperture 112 extending therethrough. The through-aperture 112 extends between the upper surface 114 of the weight body 172 to the lower surface 116 of the weight body 172 and couples the upper surface 114 to the lower surface 116, the upper surface 114 defining a generally annular shape extending about a generally circular aperture, the lower surface 116 defining a generally cruciform aperture, the generally cruciform aperture coupled to the generally circular aperture by the through-aperture 112. It is contemplated that the lift pin weight 104 be further configured for carriage by the lift pin 102 and in this respect defines a plurality of flanges 182 within the through-aperture 112, the through-aperture 112 having a first through-aperture segment 186 and a second through-aperture segment 188 separated by the plurality of flanges 182. The first through-aperture segment 186 extends axially from the upper surface 114 of the weight body 172 to the plurality of flanges 182. The first through-aperture segment 186 further defines a first segment profile 190. The second through-aperture segment 188 extends axially from the plurality of flanges 182 to the lower surface 116 of the weight body 172. The second through-aperture segment 188 further defines a second segment profile 192 and differs in shape and width from the first segment profile 190. The second through-aperture segment 188 is further axially separated from the first through-aperture segment 186 by the plurality of flanges 182, the plurality of flanges 182 intermediate the first through-aperture segment 186 and the second through-aperture segment 188 within an interior of the weight body 172.

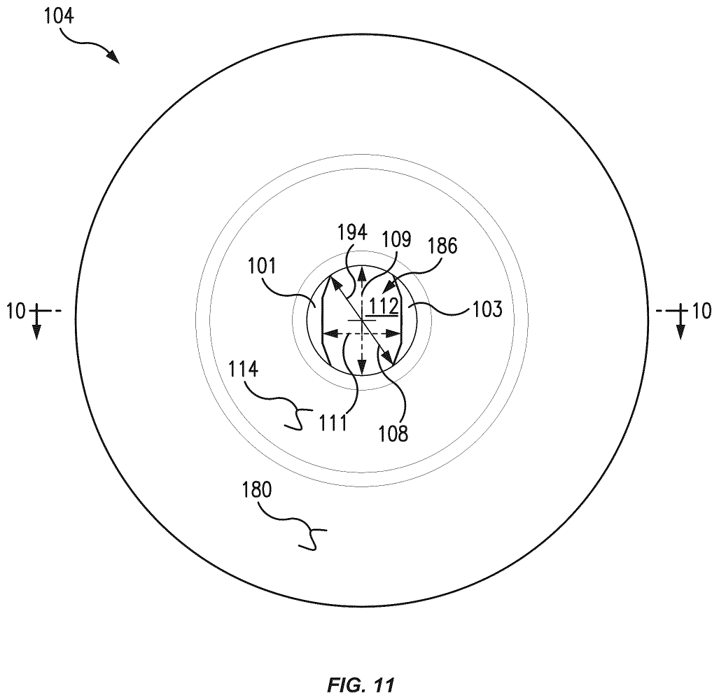

As shown in FIG. 11, the first through-aperture segment 186 is generally circular in shape, extends circumferentially about the lift pin axis 108, and defines a first segment diameter 194. In certain examples, the first segment diameter 194 may be greater than the neck diameter 134 (shown in FIG. 7) of the neck segment 128 (shown in FIG. 7). In accordance with certain examples, the first segment diameter 194 may be greater than the stem diameter 132 (shown in FIG. 7) of the stem segment 126 (shown in FIG. 7). It is contemplated that, in certain examples, the first segment diameter 194 may be greater than both the minor width 138 (shown in FIG. 9) and the major width 136 (shown in FIG. 9) of the span feature 130 (shown in FIG. 6). It is also contemplated that, in accordance with certain examples, that the first segment diameter 194 may be substantially equivalent to the stem diameter 132 of the stem segment 126 of the lift pin body 106. As will be appreciated by those of skill in the art in view of the present disclosure, this laterally fixes the lift pin weight 104 relative to the lift pin body 106 when the first through-aperture segment 186 of the through-aperture 112 laterally overlaps the stem segment 126 of the lift pin body 106.

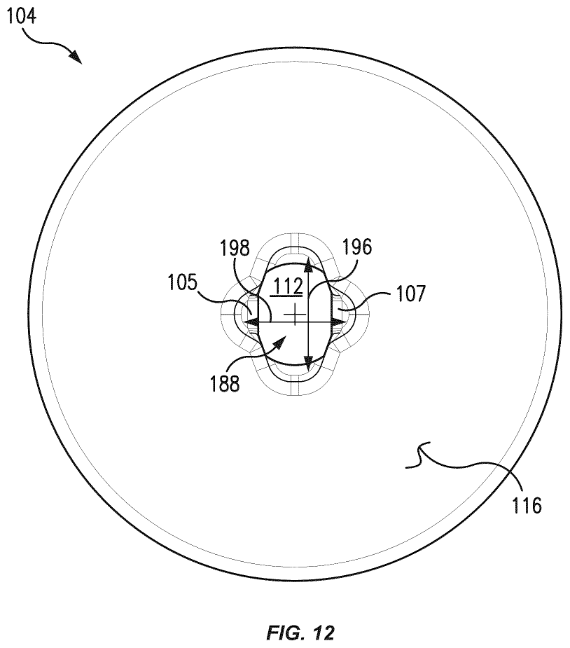

As shown in FIG. 12, the second through-aperture segment 188 of the through-aperture 112 has a generally cruciform shape between the lower surface 116 of the weight body 172 and the plurality of flanges 182. The generally cruciform shape defines a second segment major width 196 and a second segment minor width 198, the second segment minor width 198 substantially orthogonal relative to the second segment major width 196. It is contemplated that the second segment major width 196 be greater than the second segment minor width 198, that the second segment minor width 198 be less the major width 136 (shown in FIG. 9) of the span feature 130 (shown in FIG. 6), and that the second segment major width 196 of the second through-aperture segment 188 be greater than the major width 136 of the span feature 130. As will be appreciated by those of skill in the art in view of the present disclosure, this allows the span feature 130 to axially traverse the second through-aperture segment 188 when the major lobe 140 of the span feature 130 is registered to the second segment major width 196 of the second through-aperture segment 188.

With continuing reference to FIG. 11, the flanged segment 184 has a first flange portion 101 and a second flange portion 103. The first flange portion 101 protrudes into the through-aperture 112 and toward the lift pin axis 108 and has a first seating face 105 (shown in FIG. 11). The first seating face 105 is configured to seat on the first major lobe 140 (shown in FIG. 6) of the span feature 130 (shown in FIG. 6) the lower surface 116 of the weight body 172, the lift pin weight 104 thereby be carried by the lift pin 102 when the first seating face 105 abuts the first major lobe 140 of the span feature 130 of the lift pin body 106. The second flange portion 103 is similar to the first flange portion 101, is additional diametrically opposite the first flange portion 101, and has a second seating face 107 (shown in FIG. 11). The second seating face 107 is similar to the first seating face 105 and is additionally configured to seat the weight body 172 on the second major lobe 144 of the span feature 130 when the second seating face 107 abuts an upper surface of the second major lobe 144 of the span feature 130. As will be appreciated by those of skill in the art in view of the present disclosure, abutting the second seating face 107 against the upper surface of the second major lobe 144 enables the lift pin weight 104 to be carried by the lift pin 102 such that a center of gravity of the lift pin weight 104 is on the lift pin axis 108.

It is contemplated that the first flange portion 101 and the second flange portion 103 define a flanged portion major width 109 and a flanged portion minor width 111. The flanged portion minor width 111 extends between the first flange portion 101 and the second flange portion 103, is smaller than the major width 136 (shown in FIG. 9) of the span feature 130 (shown in FIG. 6), and is substantially equivalent to (or greater than) the minor width 138 (shown in FIG. 6) of the span feature 130. The flanged portion major width 109 is orthogonal relative to the flanged portion minor width 111, is larger than the flanged portion minor width 111, is larger than the minor with 138 of the span feature 130, and is substantially equivalent or larger than the major width 136 of the span feature 130. As will be appreciated by those of skill in the art in view of the present disclosure, sizing the flanged portion major width 109 to be substantially equivalent in size to the major width 136 of the span feature 130 allows the span feature 130 of the lift pin body 106 to axially traverse the flanged segment 184 of the through-aperture 112 when the lift pin weight 104 is registered to the lift pin 102 in rotation about the lift pin axis 108 such that the major width 136 of the span feature 130 overlaps the flanged portion major width 109. As will also be appreciated by those of skill in the art in view of the present disclosure, sizing the flanged portion minor width 111 to be smaller than the major width 136 of the span feature 130 enables the first flange portion 101 and the second flange portion 103 to seat of the span feature 130 of the lift pin body 106 such that the lift pin weight 104 is carried by the lift pin 102 when the lift pin weight 104 is rotated such that the flanged portion minor width 111 overlays the major width 136 of the span feature 130.

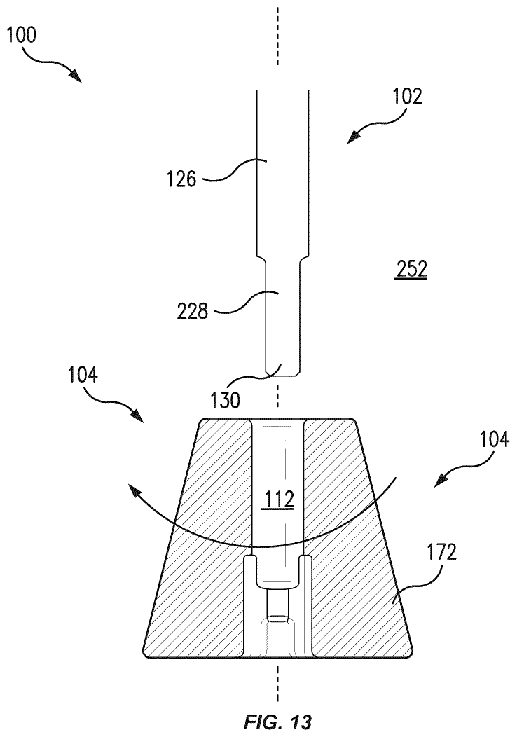

With reference to FIGS. 13-16, assembly of the lift pin arrangement 100 is shown. As shown in FIG. 13, the lift pin 102 is first slidably received within the lift pin aperture 262 (shown in FIG. 2) defined within the substrate support 224 (shown in FIG. 2). It is contemplated that that the lift pin 102 be slidably received within the lift pin aperture 262 such that the contact pad 124 seats within an upper surface of the substrate support 224 and the span feature 130 dangles within the lower chamber 252 of the chamber body 210 (shown in FIG. 2) from the substrate support 224. In this respect it is contemplated that the neck segment 128 of the lift pin body 106 and at least a portion of the stem segment 126 are axially between the span feature 130 and a lower surface of the substrate support 224. The weight body 172 is then arranged along the lift pin axis 108 within the lower chamber 252 of the chamber body 210 such that the through-aperture 112 extends about the lift pin axis 108. The weight body 172 is then rotated about the lift pin axis 108 such that the flanged portion major width 109 (shown in FIG. 11) is registered to, and axially overlays, the major width 136 (shown in FIG. 9) of the span feature 130.

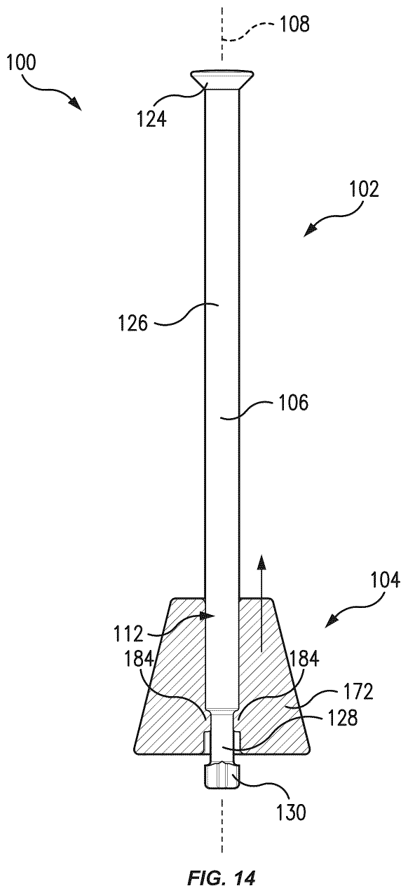

As shown in FIG. 14, the weight body 172 is next translated along the lift pin axis 108 relative to the lift pin body 106 toward the contact pad 124 of the lift pin body 106 such that the flanged segment 184 of the through-aperture 112 defined within the weight body 172 is axially between the span feature 130 and the stem segment 126 of the lift pin body 106. In this respect it is contemplated that the flanged segment 184 of the through-aperture 112 defined within the weight body 172, and more particularly the first flange portion 101 and the second flange portion 103 of the weight body 172, laterally overlap the neck segment 128 of the lift pin body 106 along the lift pin axis 108.

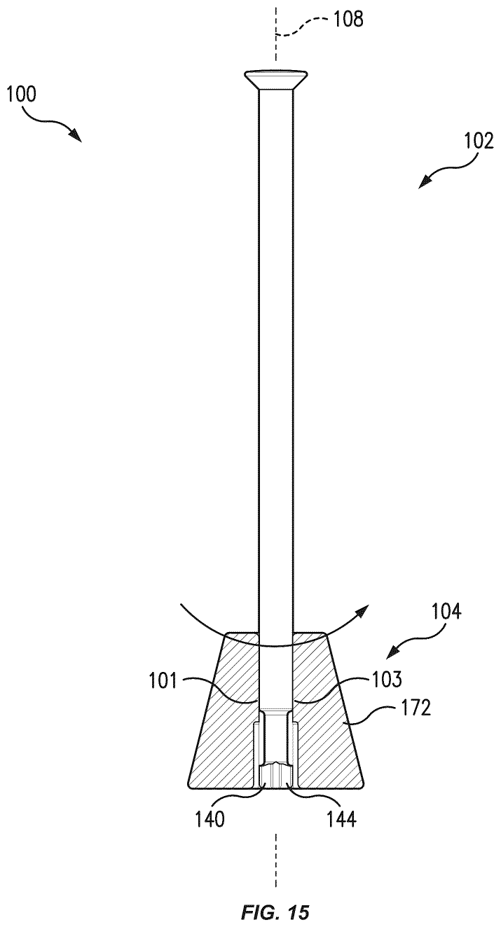

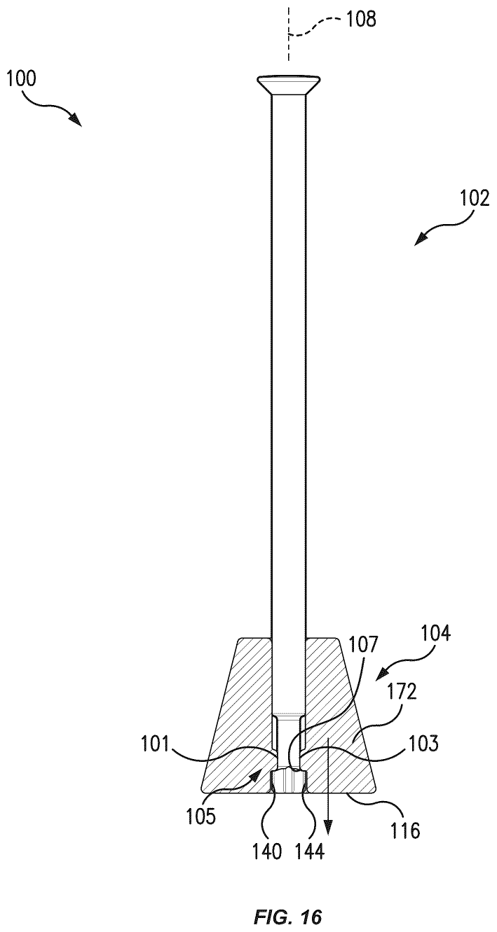

As shown in FIG. 15, the weight body 172 is next rotated about the lift pin axis 108, for example by about 90 degrees, such that the first flange portion 101 and the second flange portion 103 axially overlay the first major lobe 140 and the second major lobe 144 of the span feature 130. As shown in FIG. 16, the weight body 172 thereafter translated along the lift pin axis 108 such that the first seating face 105 and the second seating face 107 abut the upper surface of the first major lobe 140 and the upper surface of the second major lobe 144 of the span feature 130, respectively.

As will be appreciated by those of skill in the art in view of the present disclosure, this fixes the lift pin weight 104 of the lift pin 102 at the span feature 130 such that the lift pin 102, and therethrough the substrate support 224 (shown in FIG. 2), carry the lift pin weight 104. As will also be appreciated by those of skill in the art in view of the present disclosure, the first seating face 105 and the second seating face 107 may be axially offset from the lower surface 116 of the weight body 172 at a distance substantially equivalent to a vertical height of the first major lobe 140 and the second major lobe 144, limiting (or preventing entirely) axial translation of the lift pin weight 104 relative to the lift pin 102 during movement of the lift pin actuator 230 (shown in FIG. 2) prior to movement of the lift pin 102 between the first position 264 (shown in FIG. 2) and the second position 266 (shown in FIG. 2).

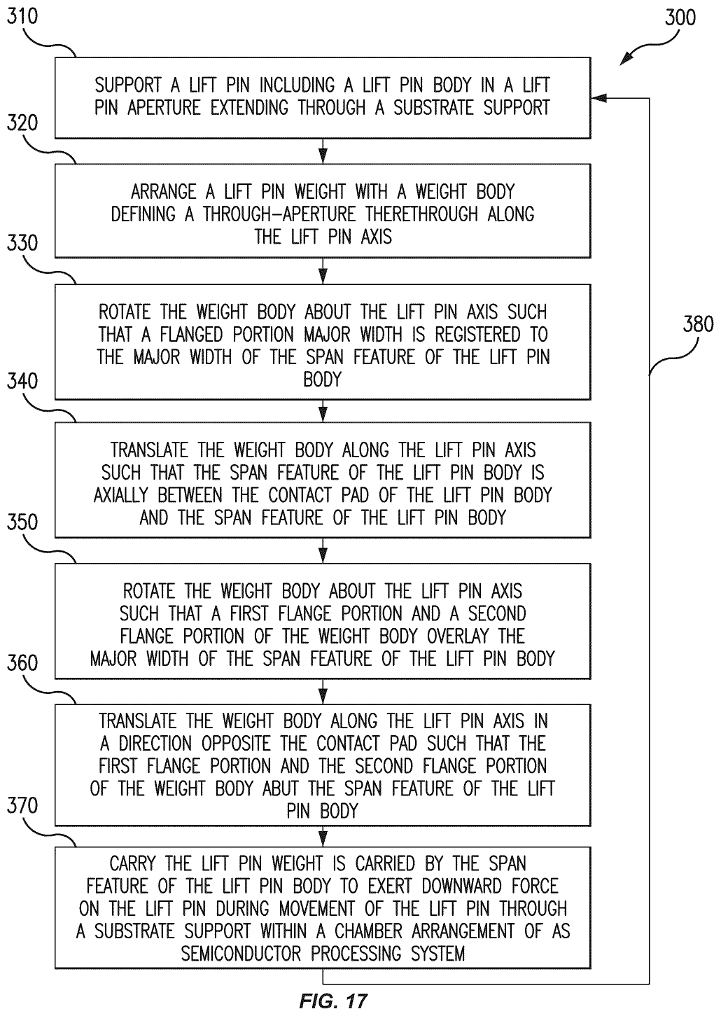

With reference to FIG. 17, a method 300 of making a lift pin arrangement for a semiconductor processing system, e.g., the lift pin arrangement 100 (shown in FIG. 1) for the semiconductor processing system 200 (show in FIG. 1), is shown. The method 300 includes supporting a lift pin including a lift pin body in a lift pin aperture extending through a substrate support, e.g., the lift pin 102 (shown in FIG. 2) including the lift pin body 106 (shown in FIG. 6) within the lift pin aperture 262 (shown in FIG. 2) extending through the substrate support 224 (shown in FIG. 2), as shown with box 310. The method 300 also includes arranging a lift pin weight with a weight body defining a through-aperture therethrough along a lift pin axis defined by the lift pin body, e.g., the lift pin weight 104 (shown in FIG. 2) including the weight body 172 (shown in FIG. 10) defining the through-aperture 112 (shown in FIG. 10) along the lift pin axis 108 (shown in FIG. 6), as shown box 320. The method 300 further includes rotating the weight body about the lift pin axis such that a flanged portion major width defined within the through-aperture of the weight body is registered to a major width of a span feature of the lift pin body, e.g., the flanged portion major width 109 (shown in FIG. 11) is registered to the major width 136 (shown in FIG. 6) of the span feature 130 (shown in FIG. 6), and the weight body translated along the lift pin axis such that the span feature of the lift pin body is axially between a contact pad of the lift pin body and the span feature of the lift pin body, e.g., the contact pad 124 (shown in FIG. 6), as shown with box 330 and box 340.

The weight body is then rotated about the lift pin axis such that a first flange portion and a second flange portion of the weight body axially overlay the major width of the span feature of the lift pin body, e.g., the first flange portion 101 (shown in FIG. 11) and the second flange portion 103 (shown in FIG. 11) overlay the major width of the span feature of the lift pin body, and the weight body translated along the lift pin axis in a direction axially opposite the contact pad of the lift pin body such that the first flange portion and the second flange portion of the weight body abut the span feature of the lift pin body, as shown with box 350 and box 360. It is contemplated that abutment of the first flange portion and the second flange portion on the span feature be such that the lift pin body exert a downward force on the lift pin during sliding movement of the lift pin through the substrate support, for example during movement between the first position and the second position of the lift pin through the substrate support during seating and unseating of substrates within the chamber arrangement of the semiconductor processing system. It is also contemplated that the lift pin arrangement may be one of three (3) lift pin arrangements included in the semiconductor processing systems, as shown with arrow 380.

Semiconductor processing systems such as semiconductor processing systems employed to deposit material layers using chemical vapor deposition techniques such as epitaxy and atomic layer deposition techniques commonly require that a substrate be seated on a substrate support prior to material layer deposition and thereafter be unseated from the substrate support subsequent to material layer deposition. Seating and unseating of the substrate from the substrate support may be accomplished using lift pins, which may move relative to the substrate support between a retracted position and an extended position or to seat and unseat the substrate from the substrate support, or which may be recessed or protrude from the substrate support as a result of the substrate support being driven between a processing position and a load/unload position. As has been explained above, in some deposition processes, lift pins may bind within the substrate support, such as when the lift pin tilts within the lift pin aperture and/or due when material accretes on the lift pin and/or accumulates within the lift pin aperture receiving the lift pin, potentially interruption operation of the semiconductor processing systems.

In examples described herein lift pin arrangements are provided that include a lift pin and a lift pin weight supported by the lift pin. Advantageously, the lift pin weight establishes a center of gravity of the lift pin arrangement that is below that of the lift pin, increasing magnitude of the horizontal force component required to tilt the lift pin and thereby limiting tendency of the lift pin to bind within the lift pin aperture due to tilting. To further advantage, the lift pin weight increases downward force on the lift pin, increasing resistance that accreted material need exert on the lift pin to bind the lift pin within the lift pin aperture, limiting tendency that such material accretion may have to cause the lift pin within the lift pin aperture.

In examples described herein the lift pin has a lift pin body including a contact pad and an opposite span feature separated by a neck segment, the lift pin weight have a through aperture, and the lift pin weight is attached to the lift pin by receiving the lift pin within the through-aperture and seating the lift pin weight on the span feature. The lift pin weight may fixed in rotation about the lift pin either geometry defined by the span feature and/or within the through-aperture extending through the lift pin weight, as well as through cooperation of a keeper received about the lift pin. As will be appreciated by those of skill in the art in view of the present disclosure, this may simplify assembly of the lift pin assembly, for example, by avoiding the need for fasteners and/or the employment of tools to assemble the lift pin arrangement as well as provide the aforementioned advantages with respect to lift pin reliability during operation of the semiconductor processing system employing the lift pin arrangement.

The illustrations presented herein are not meant to be actual views of any particular material, structure, or device, but are merely idealized representations that are used to describe embodiments of the disclosure. The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A lift pin, comprising:
a lift pin body arranged along a lift pin axis, the lift pin body having:
a contact pad defined at a first end of the lift pin body;
a stem segment extending from the contact pad;
a neck segment extending from the stem segment; and
a span feature defined at a second end of the lift pin body and connected to the contact pad by the neck segment and the stem segment of the lift pin body,
wherein the span feature has a minor width and a major width, the minor width substantially equivalent to a neck diameter defined by the neck segment of the lift pin body and greater than the minor width, the major width greater than a stem diameter defined by the neck segment of the lift pin body.

2. The lift pin of claim 1, wherein the lift pin body is formed from a ceramic material.

3. The lift pin of claim 1, wherein the minor width is offset from the major width by about 90 degrees about the lift pin axis.

4. The lift pin of claim 1, wherein the span feature has a major lobe and a minor lobe, the major width spanning the major lobe, the minor width spanning the minor lobe.

5. The lift pin of claim 4, wherein the major lobe is a first major lobe and the span feature has a second major lobe that is separated from the first major lobe by the minor lobe.

6. The lift pin of claim 5, wherein the second major lobe is offset from the first major lobe by about 180 degrees.

7. The lift pin of claim 4, wherein the minor lobe is a first minor lobe and the span feature has a second minor lobe, wherein the second minor lobe is separated from the first minor lobe by the major lobe.

8. The lift pin of claim 7, wherein the second minor lobe is offset from the first minor lobe by about 180 degrees.

9. The lift pin of claim 1, wherein the span feature has a first planar facet and a second planar facet, and wherein the minor width intersects both the first planar facet and the second planar facet.

10. The lift pin a claim 9, wherein the span feature has two or more arcuate facets defined between the major width and the minor width.

11. The lift pin of claim 10, wherein the span feature has an intermediate planar facet offset from both the major width and the minor width.

12. The lift pin of claim 9, wherein the first planar facet and the second planar facet are two of at least six planar facets defined by the span feature, wherein the span feature has at least eight arcuate facets.

13. A lift pin arrangement, comprising:
a lift pin as recited in claim 1;
a lift pin weight including a weight body with a through-aperture extending therethrough, the through-aperture having a flanged segment; and
wherein the lift pin weight is carried by the span feature of the lift pin body through a first flange portion and a second flange portion of the flanged segment of the through-aperture and extending radially toward the lift pin axis defined by the lift pin body of the lift pin.

14. The lift pin arrangement of claim 13, wherein the through-aperture has a first through-aperture segment and a second through-aperture segment separated by a plurality of flanges, the first through-aperture segment coupling an upper surface of the weight body to the plurality of flanges, the second through-aperture segment coupling the plurality of flanges to a lower surface of the weight body.

15. The lift pin arrangement of claim 14, wherein the first through-aperture segment has a generally circular shape between the upper surface of the weight body and the plurality of flanges within the through-aperture, and wherein the second through-aperture segment has a generally cruciform shape extending between the lower surface of the weight body and the plurality of flanges within the through-aperture.

16. The lift pin arrangement of claim 14, wherein the first through-aperture segment has a diameter that is substantially equivalent to a width of the stem segment of the lift pin body, wherein the second through-aperture segment has a second segment major width that is greater than the major width of the span feature of the lift pin body, and wherein the second through-aperture segment has a second segment minor width that is less than the major width of the span feature of the lift pin body.

17. The lift pin arrangement of claim 14, wherein the lift pin weight has a frustoconical shape, wherein the first through-aperture segment has a diameter that is substantially equivalent to a width of the stem segment of the lift pin body, wherein the second through-aperture segment has a second segment major width that is substantially equivalent to the major width of the span feature of the lift pin body.

18. A semiconductor processing system, comprising:
a chamber body formed from a quartz material;
a substrate support arranged within an interior of the chamber body and configured to support a substrate during deposition of a material layer onto the substrate;
a lift pin as recited in claim 1 slidable received within a lift pin aperture extending through the substrate support; and
a lift pin weight with a through-aperture extending therethrough, a portion of the stem segment and the span feature arranged within the through-aperture of the lift pin weight, the lift pin weight carried by the lift pin through the span feature and the neck segment of the lift pin.

19. The semiconductor processing system of claim 18, wherein the lift pin body is formed from silicon carbide, and wherein a weight body of the lift pin weight is formed from quartz.

20. A method of making a lift pin arrangement for a semiconductor processing system, the method comprising:
at a lift pin including a lift pin body arranged along a lift pin axis having a contact pad defined at a first end of the lift pin body, a stem segment extending from the contact pad, a neck segment extending from the stem segment, and span feature defined at a second end of the lift pin body and connected to the contact pad by the neck segment and the stem segment of the lift pin body, the span feature having a minor width and a major width, the minor width substantially equivalent to a neck diameter defined by the neck segment of the lift pin body, the major width greater than the minor width, the major width greater than a stem diameter defined by the neck segment of the lift pin body,
arranging a lift pin weight with a weight body defining a through-aperture therethrough along the lift pin axis;
rotating the weight body about the lift pin axis such that a flanged portion major width is registered to the major width of the span feature of the lift pin body;
translating the weight body along the lift pin axis such that the span feature is axially between the contact pad of the lift pin body and the span feature of the lift pin body;
rotating the weight body about the lift pin axis such that a first flange portion and a second flange portion of the weight body overlay the major width of the span feature of the lift pin body; and
translating the weight body along the lift pin axis in a direction opposite the contact pad such that the first flange portion and the second flange portion of the weight body abut the span feature of the lift pin body,
whereby the lift pin weight is carried by the span feature of the lift pin body to exert downward force on the lift pin during movement of the lift pin through a substrate support within a chamber arrangement of the semiconductor processing system.
